(19) United States
(12) Patent Application Publication
(10) Pub. No.: US 2015/0109034 A1
(43) Pub. Date: Apr. 23, 2015

(54) DELAY ARCHITECTURE FOR REDUCING DOWNTIME DURING FREQUENCY SWITCHING

(71) Applicant: QUALCOMM INCORPORATED, San Diego, CA (US)

(72) Inventors: Narasimhan Vasudevan, San Diego, CA (US); Zhiqin Chen, San Diego, CA (US); Li Pan, Portland, OR (US); Michael Thomas Fertsch, San Diego, CA (US); Nan Chen, San Diego, CA (US)

(73) Assignee: QUALCOMM INCORPORATED, San Diego, CA (US)

(21) Appl. No.: 14/056,861

(22) Filed: Oct. 17, 2013

(51) Int. Cl. H03L 7/08

(52) U.S. Cl. CPC H03L 7/08
USPC 327/156

(57) ABSTRACT

A delay architecture for reducing downtime during frequency switching is described herein. In one embodiment, an adjustable delay circuit comprises a phase-locked loop (PLL) or a delay-locked loop (DLL) configured to generate a bias voltage, and a plurality of delay elements coupled in series, wherein each of the delay elements is biased by the bias voltage. The adjustable delay circuit also comprises a multiplexer coupled to outputs of two or more of the delay elements, wherein each of the outputs corresponds to a different delay of an input signal, and wherein the multiplexer is configured to select one of the outputs based on a data frequency of a memory interface.

### BACKGROUND

1. Field

Aspects of the present disclosure relate generally to memory, and more particularly, to a delay architecture for reducing downtime during frequency switching.

2. Background

A chip may include a memory interface for interfacing circuits (e.g., a memory controller) on the chip with an external memory device, such as a dynamic random access memory (DRAM). The memory interface may support data frequency switching, in which the rate at which data is sent to and received from the memory device can be dynamically adjusted. For example, the data frequency may be increased for applications requiring a high data rate, and may be decreased for applications that do not require a high data rate to reduce power consumption.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to an aspect, an adjustable delay circuit is described herein. The delay circuit comprises a phase-locked loop (PLL) configured to generate a bias voltage, and a plurality of delay elements coupled in series, wherein each of the delay elements is biased by the bias voltage. The delay circuit also comprises a multiplexer coupled to outputs of two or more of the delay elements, wherein each of the outputs corresponds to a different delay of an input signal, and wherein the multiplexer is configured to select one of the outputs based on a data frequency of a memory interface.

A second aspect relates to an adjustable delay circuit. The delay circuit comprises a delay-locked loop (DLL) configured to generate a bias voltage, and a plurality of delay elements coupled in series, wherein each of the delay elements is biased by the bias voltage. The delay circuit also comprises a multiplexer coupled to outputs of two or more of the delay elements, wherein each of the outputs corresponds to a different delay of an input signal, and wherein the multiplexer is configured to select one of the outputs based on a data frequency of a memory interface.

A third aspect relates to a method for signal delay. The method comprises generating a bias voltage using a phase-locked loop (PLL) or a delay-locked loop (DLL), biasing each one of a plurality of delay elements with the bias voltage, wherein the plurality of delay elements are coupled in series, and selecting an output of one of the plurality of delay elements based on a data frequency of a memory interface.

A fourth aspect relates to an apparatus for signal delay. The apparatus comprises means for generating a bias voltage, means for biasing each one of a plurality of delay elements with the bias voltage, wherein the plurality of delay elements are coupled in series, and means for selecting an output of one of the plurality of delay elements based on a data frequency of a memory interface.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows an example of a memory interface for interfacing with an external memory device.

FIG. 2 is a timing diagram illustrating an example of timing between a data signal and a data strobe.

FIG. 3 shows an example of a phase-locked loop (PLL) used for frequency switching.

FIG. 4 shows an example of a delay-locked loop (DLL) used for frequency switching.

FIG. 5 shows a delay device for reducing downtime during frequency switching according to an embodiment of the present disclosure.

FIG. 6 shows a memory interface in which two delay devices share a master PLL/DLL according to an embodiment of the present disclosure.

FIG. 7 shows a memory interface in which de-skew devices share a master PLL/DLL according to an embodiment of the present disclosure.

FIG. 8 shows a memory interface in which de-skew devices share a master PLL/DLL according to another embodiment of the present disclosure.

FIG. 9 is a flow diagram illustrating a method for signal delay according to an embodiment of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

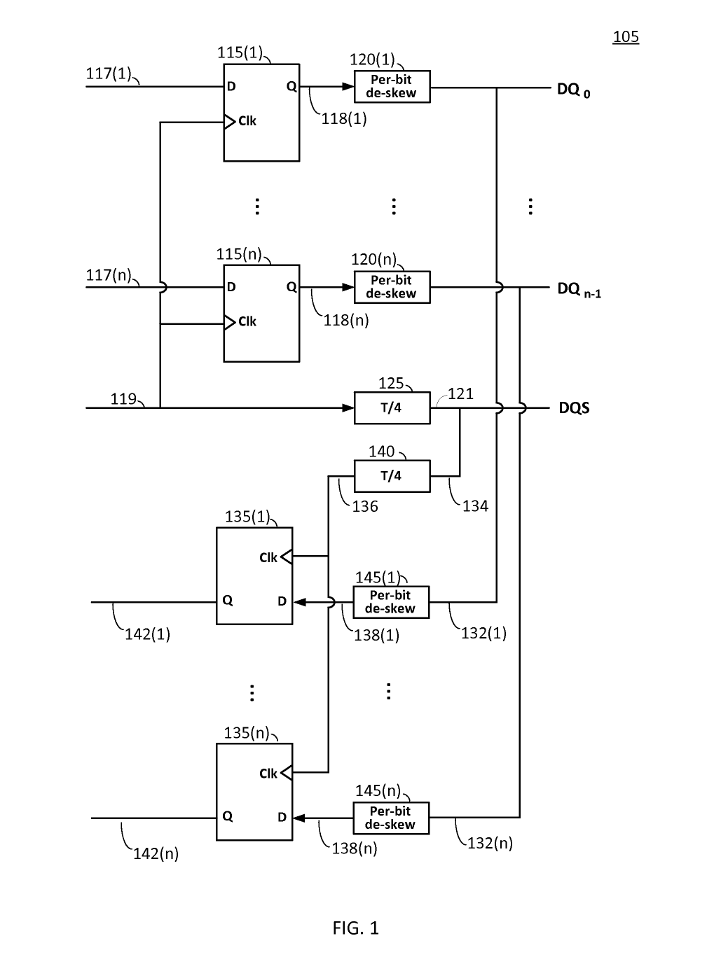

A chip may include a memory interface for interfacing circuits (e.g., a memory controller) on the chip with an external memory device, such as a dynamic random access memory (DRAM). FIG. 1 shows a memory interface 105 for interfacing a chip with an external DRAM. The memory interface 105 includes a plurality of write flip-flops 115(1)-115(n), a first plurality of per-bit de-skew devices 120(1)-120(n), a plurality of read flip-flops 135(1)-135(n), a second plurality of per-bit de-skew devices 145(1)-145(n), a first delay device 125, and a second delay device 140.

During write operations, the write flip-flops 115(1)-115(n) receive a plurality of data signals 117(1)-117(n) in parallel. Each write flip-flop 115(1)-115(n) also receives a data strobe signal 119, which may be a periodic signal having half the frequency of the incoming data signals 117(1)-117(n). Each flip-flop 115(1)-115(n) captures data bits from the respective data signal 117(1)-117(n) on the rising and falling edges of the data strobe signal 119, and outputs the captured data bits to the respective per-bit de-skew device 120(1)-120(n), which is described in more detail below.

The data strobe signal 119 is also input to the first delay device 125. Before the first delay device 125, the edges of the data strobe signal 119 are approximately aligned with transitions of the output data signals 118(1)-118(n) of the write flip-flops 115(1)-115(n). This is because each flip-flop 115(1)-115(n) captures data bits for the respective output data signal 118(1)-118(n) on the rising and falling edges of the data strobe signal 119. The first delay device 125 delays the data strobe signal 119 by a quarter of a period so that the edges of the delayed data strobe signal 121 are approximately centered between transitions of the output data signals 118(1)-118(n).

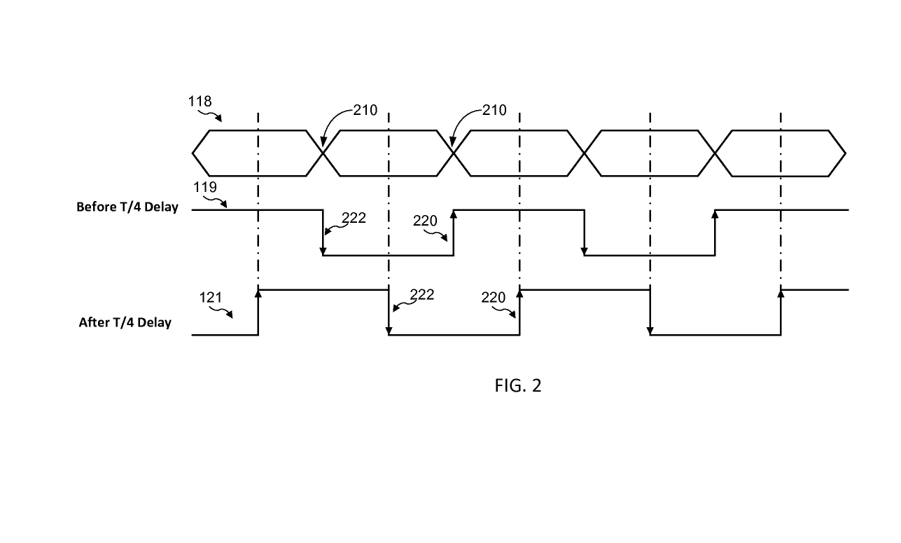

FIG. 2 shows a simplified example of the timing relationship between one of the output data signals 118 and the data strobe signal 119. In this example, the rising and falling edges 220 and 222 of the data strobe signal 119 are approximately aligned with the transitions 210 of the output data signal 118 before the delay. After being delayed by a quarter of a period delay (T/4), the rising and falling edges 220 and 222 of the data strobe signal 121 are approximately centered between the transitions 210 of the output data signal 118, as shown in FIG. 2.

Each per-bit de-skew device 120(1)-120(n) adds a small amount of delay to the respective data signal 118(1)-118(n) to compensate for skew between the data signal and the data strobe signal 121 in going from the memory interface 105 to the external DRAM. This delay may be referred to as de-skew delay. The skew may be due to a mismatch in the lengths of the lines used to transport the data signal and the data strobe signal to the DRAM and/or another cause. After being delayed by the respective per-bit de-skew device 120(1)-120(n), each output data signal is output to the DRAM on a respective bi-directional data line DQ₀-DQₙ₋₁. The data strobe signal 121 is output to the DRAM on a bi-directional strobe line DQS. The DRAM uses the data strobe signal 121 to capture data bits from the data signals received from the memory interface 105.

During read operations, the memory interface 105 receives a plurality of data signals 132(1)-132(n) from the DRAM via the bi-directional data lines DQ₀-DQₙ₋₁ and a data strobe signal 134 from the DRAM via the bi-directional strobe line DQS. Each of the second plurality of per-bit de-skew devices 145(1)-145(n) receives one of the data signals 132(1)-132(n) and adds a small amount of delay to the respective data signal to compensate for skew between the data signal and the data strobe signal 134. This delay may be referred to as de-skew delay.

Although the memory interface 105 communicates with the DRAM over bi-directional lines in the example given above, it is to be appreciated that the memory interface 105 may communicate with the DRAM over uni-directional lines. For example, the memory interface 105 may output data signals to the DRAM via a first set of uni-directional data lines, and receive data signals from the DRAM via a second set of uni-directional data lines.

The data strobe signal 134 from the DRAM is input to the second delay device 140, which delays the data strobe signal 134 by a quarter of a period. This is done because the DRAM outputs the data strobe signal 134 with the edges of the data strobe signal aligned with transitions of the data signals 132(1)-132(n). By delaying the data strobe signal 134 by a quarter of a period, the second delay device 140 approximately centers the edges of the delayed data strobe signal 136 between transitions of the data signals 132(1)-132(n).

The delayed data strobe 136 is then input to the clock input of each read flip-flop 135(1)-135(n). For example, the delayed data strobe signal 136 may be distributed to the clock inputs of the read flip-flops 135(1)-135(n) using a clock tree. Each read flip-flop 135(1)-135(n) captures data bits from the output 138(1)-138(n) of the respective per-bit de-skew device 145(1)-145(n) on the rising and falling edges of delayed data strobe signal 136. The resulting output data signals 142(1)-142(n) may be sent to additional circuitry (not shown) in the memory interface 105 for further processing.

The memory interface 105 is an example of a bi-directional memory interface capable of transmitting data to and receiving data from the DRAM over the same lines (i.e., bi-directional lines DQ₀-DQₙ₋₁). Further, the memory interface 105 is capable of transmitting a plurality of bits simultaneously to the DRAM over the bi-directional lines DQ₀-DQₙ₋₁ and receiving a plurality of bits simultaneously from the DRAM over the bi-directional lines DQ₀-DQ₋₁. In one example, the number of bits that are simultaneously transmitted or received may be eight (one byte), in which case the bi-directional lines may be denoted DQ₀-DQ₇.

The memory interface 105 may support data frequency switching, in which the rate at which data is sent to and received from the DRAM can be dynamically adjusted. For example, the data frequency may be increased for applications requiring a high data rate, and may be decreased for applications that do not require a high data rate to reduce power consumption. When the data frequency changes, the delays of the delay devices 125 and 140 need to be adjusted accordingly. For example, when the data frequency is doubled, the period of the data strobe signal 119 is reduced in half As a result, the delay of the first delay device 125 also needs to be reduced in half to maintain a delay of a quarter of a period for the data strobe signal 119.

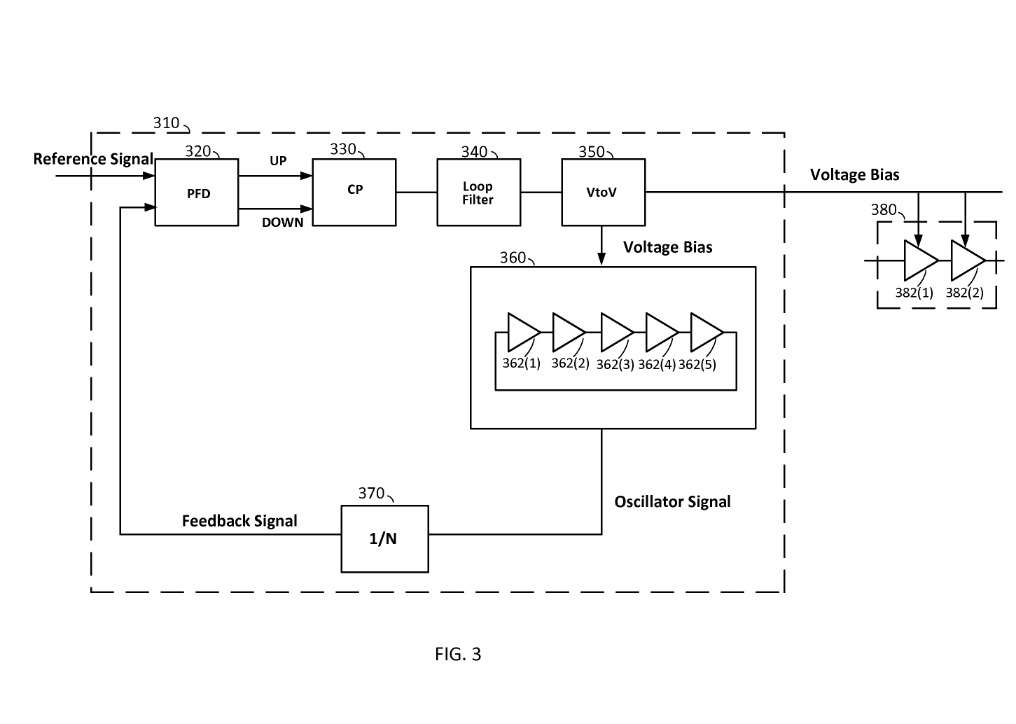

The delay of each delay device 125 and 140 may be adjusted using a phase-locked loop (PLL) or a delay-locked loop (DLL). FIG. 3 shows an example in which a PLL 310 is used to adjust the delay of a delay device 380. The delay device 380 may be used to implement the first delay device 125 or the second delay device 140. The delay device 380 comprises a plurality of delay elements 382(1) and 382(2) (e.g., buffers) coupled in series, in which the delay of each delay element is controlled by a voltage bias input to the delay element 382(1) and 382(2). The PLL 310 adjusts the delay of the delay device 380 by adjusting the voltage bias, as discussed further below.

The PLL 310 comprises a phase-frequency detector (PFD) 320, a charge pump 330, a loop filter 340 (e.g., an RC filter), a voltage-to-voltage converter 350, an oscillator 360, and a frequency divider 370. The oscillator 360 comprises a plurality of delay elements 362(1)-362(5) (e.g., buffers) coupled into a closed loop. The delay elements 362(1)-362(5) may be inverting so that the closed loop causes the delay elements 362(1)-362(5) to oscillate at an oscillator frequency that is inversely proportional to the delay of the delay elements 362(1)-362(5). The oscillator frequency may be given by:

$$f = \frac{1}{2 \cdot M \cdot {t}_{d}} \qquad ( 1 )$$

where f is the oscillator frequency, M is the number of delay elements in the oscillator 360, and t_{d} is the delay of each delay element 362(1)-362(5). Equation (1) assumes that each of the delay elements has approximately the same delay. The oscillator frequency is more generally given by:

$$f = \frac{1}{2 \cdot {T}_{d}} \qquad ( 2 )$$

where T_{d} is the total delay of the delay elements 362(1)-362(5).

Thus, the oscillator 360 outputs an oscillator signal having a frequency that is inversely proportional to the delay of the delay elements 362(1)-362(5) in the oscillator 360. The delay of the delay elements 362(1)-362(5), and hence the oscillator frequency, is controlled by a voltage bias input to the delay elements 362(1)-362(5) from the voltage-to-voltage converter 350.

In operation, the oscillator signal from the oscillator 360 is frequency divided by the frequency divider 370 to produce a feedback signal. The feedback signal and a reference signal are input to the PFD 320, which detects a phase error between the feedback signal and the reference signal. The reference signal may be generated by a crystal oscillator or another source. The PFD 320 outputs an UP signal and/or a DOWN signal to the charge pump 330 based on the detected phase error. The charge pump 330 converts the UP signal and/or DOWN signal into a current that is output to the loop filter 340. The loop filter 340 converts the current into a voltage that is output to the voltage-to-voltage converter 350. The voltage-to-voltage converter 350 converts the voltage from the loop filter 340 into a voltage bias that is input to the delay elements 382(1) and 382(2) in the delay device 380 and the delay elements 362(1)-362(5) in the oscillator 360.

The feedback loop of the PLL 310 adjusts the voltage bias in a direction that reduces the phase error between the reference signal and the feedback signal. This forces the oscillator frequency to be approximately equal to N times the frequency of the reference signal, where N is the divisor of the frequency divider 370. Thus, the oscillator frequency can be adjusted by adjusting the frequency of the reference signal and/or adjusting the divisor N of the frequency divider 370. Since the oscillator frequency is inversely proportional to the delay of the delay elements 362(1)-362(5) in the oscillator 360, the delay of the delay elements 362(1)-362(5) can be adjusted to a desired value by adjusting the frequency of the reference signal and/or adjusting the divisor N of the frequency divider 370 accordingly.

The delay elements 362(1)-362(5) in the oscillator 360 may have the same structure or similar structure as the delay elements 382(1) and 382(2) in the delay device 380. This allows the delay of the delay device 380 to be precisely adjusted to a desired delay by adjusting the frequency of the reference signal and/or adjusting the divisor N of the frequency divider 370 in the PLL 310 accordingly.

Thus, when the data frequency changes, the delay of the delay device 380 can be adjusted accordingly by adjusting the frequency of the reference signal and/or adjusting the divisor N of the frequency divider 370 in the PLL 310. For example, if the data frequency is doubled, the delay of the delay device 380 can be reduced in half by doubling the frequency of the reference signal or doubling the divisor N of the frequency divider 370 in the PLL 310. However, when the reference frequency or the divisor N is adjusted, it takes time for the PLL 310 to relock (e.g., on the order of 10 s of μsec). During this time, the delay of the delay device 380 is not stable, and therefore data traffic needs to be put on hold until the PLL 310 has relocked. As a result, when the data frequency changes, data traffic needs to be suspended for a period of time (downtime) to allow the PLL 310 to relock, which reduces performance

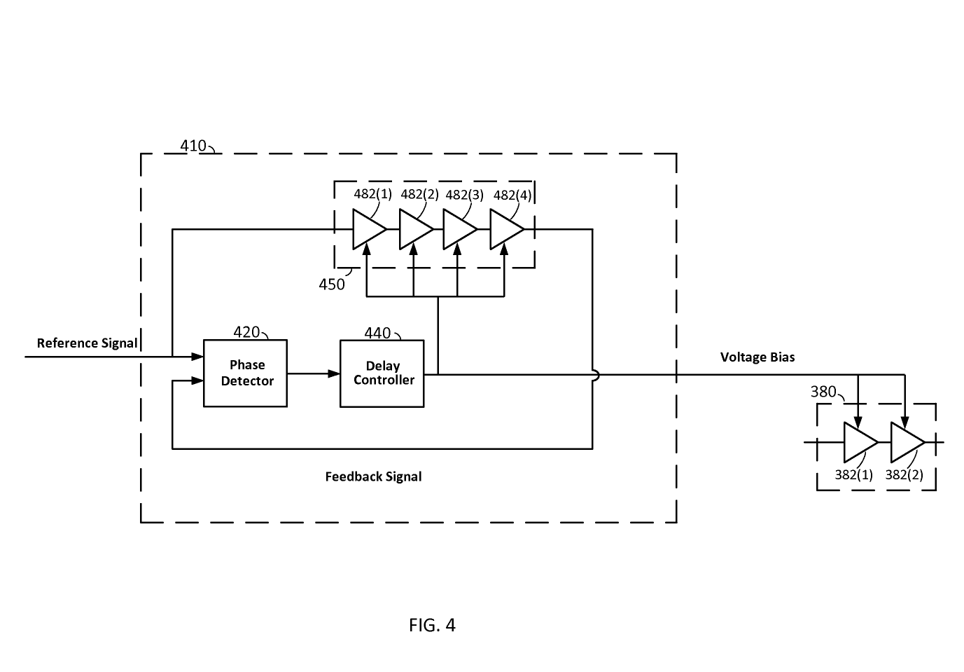

FIG. 4 shows an example in which a DLL 410 is used to adjust the delay of a delay device 380. The DLL 410 adjusts the delay of the delay device 380 by adjusting the voltage bias to the delay elements 382(1) and 382(2) in the delay device 380, as discussed further below. The DLL 410 comprises a phase detector 420, a delay controller 440, and a delay chain 450. The delay chain 450 comprises a plurality of delay elements 482(1)-482(4) coupled in series. The delay controller 440 adjusts the delays of the delay elements 482(1)-482(4) by adjusting the voltage bias to the delay elements 482(1)-482(4).

In operation, a reference signal is input to a first input of the phase detector 420. The reference signal is also passed through the delay chain 450 to produce a feedback signal, which is a delayed version of the reference signal. The feedback signal is input to a second input of the phase detector 420. The phase detector 420 detects a phase error between the reference signal and the feedback signal, and outputs a signal based on the phase error to the delay controller 440. The delay controller 440 adjusts the voltage bias, and hence the delay of the delay elements 482(1)-428(4) in the delay chain 450, in a direction that reduces the phase error.

In one aspect, the phase error approaches zero when the total delay of the delay chain 450 is approximately equal to one period of the reference signal. Thus, in this aspect, the delay controller 440 adjusts the total delay of the delay chain 450 to be approximately equal to one period of the reference signal. The delay of each delay element 482(1)-482(4) may be given by T/M where T is the period of the reference signal and M is the number of delay elements. This assumes that each delay element 482(1)-482(4) has approximately the same delay. Since the period of the reference signal is inversely proportional to the frequency of the reference signal, the delay of each element 482(1)-482(4) can be adjusted by adjusting the frequency of the reference signal.

The delay elements 482(1)-482(4) in the delay chain 450 may have the same structure or similar structure as the delay elements 382(1) and 382(2) in the delay device 380. This allows the delay of the delay device 380 to be precisely adjusted to a desired delay by adjusting the frequency of the reference signal accordingly. Thus, when the data frequency changes, the delay of the delay device 380 can be adjusted accordingly by adjusting the frequency of the reference signal input to the DLL 410. However, when the reference frequency is adjusted, it takes time for the DLL 410 to relock. During this time, the delay of the delay device 380 is not stable, and therefore data traffic needs to be put on hold until the DLL 410 has relocked. As a result, when the data frequency changes, data traffic needs to be suspended for a period of time (downtime) to allow the DLL 410 to relock, which reduces performance.

To avoid downtime associated with data frequency switching, the memory interface may include multiple PLLs/DLLs operating at different frequencies. In this approach, each of the PLLs/DLLs outputs a different bias voltage corresponding to a different delay. The PLLs/DLLs are coupled to the delay device 380 through a multiplexer, which selectively outputs the bias voltage of the PLL/DLL corresponding to the delay for the current data frequency. A drawback of this approach is that using multiple PLLs/DLLs consumes more power and chip area.

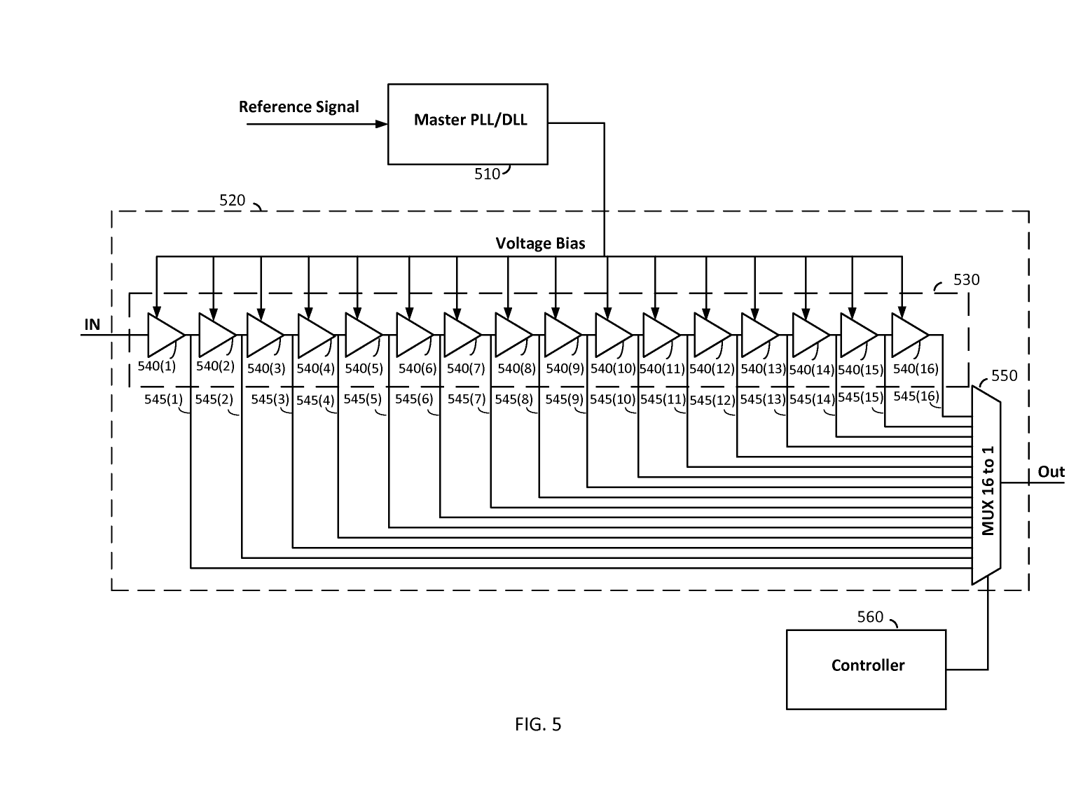

FIG. 5 shows a delay device 520 according to an embodiment of the present disclosure. The delay device 520 may be used to implement the first delay device 125 or the second delay device 140. The delay device 520 comprises a plurality of delay elements 540(1)-540(16) (e.g., buffers) coupled in series, and a multiplexer 550. Each of the delay elements 540(1)-540(16) is biased with a voltage bias from a master PLL/DLL 510, where PLL/DLL refers to a PLL or a DLL.

The master PLL/DLL 510 may normally run at a relatively constant frequency that is independent of the data frequency, in which the reference signal input to the PLL/DLL 510 is relatively constant and/or the divisor N of the frequency divider 370 is relatively constant. Thus, the master PLL/DLL 510 outputs a relatively constant voltage bias to the delay elements 540(1)-540(16) in the delay device 520 that is independent of the data frequency. Because the bias voltage is relatively constant, each of the delay elements 540(1)-540(16) provides a step delay that is relatively constant and independent of the data frequency.

The delay elements 540(1)-540(16) form a delay chain 530, in which the output 545(1)-545(16) of each delay element 540(1)-540(16) provides a different amount of delay to the signal received at the input (denoted “IN”) of the delay device 520. In other words, the output 545(1)-545(16) of each delay element 540(1)-540(16) provides a delay that is a different multiple of the step delay. The outputs 545(1)-545(16) of the delay elements 540(1)-540(16) are coupled to the multiplexer 550, which selects one of the outputs 545(1)-545(16) under the control of a controller 560, and couples the selected output to the output (denoted “OUT”) of the delay device 520. Thus, the controller 560 controls the delay of the delay device 520 by instructing the multiplexer 550 to select the output 545(1)-545(16) of the delay element 540(1)-540(16) corresponding to a desired delay.

In one embodiment, the delay device 520 is used to implement the first delay device 125 in the memory interface 105, in which the delay device 520 delays the data strobe signal 119 by a quarter of a period. In this embodiment, the controller 560 may receive a signal indicating the current data frequency of the memory interface 105, and instruct the multiplexer 420 to select the output 545(1)-545(16) of the delay element 540(1)-540(16) corresponding to a delay of a quarter of a period for the current data frequency. The controller 560 may do this using a lookup data that maps different data frequencies to different outputs 545(1)-545(16) of the delay elements 540(1)-540(16). When the controller 560 receives a signal indicating the current data frequency, the controller 560 may look up the corresponding output 545(1)-545(16) in the lookup table, and instruct the multiplexer 550 to select the corresponding output 545(1)-545(16).

When the data frequency of the memory interface 105 changes to a new data frequency, the controller 560 receives a signal indicating the new data frequency. The controller 560 then instructs the multiplexer 550 to switch to the output 545(1)-545(16) corresponding to the new data frequency. For example, when the data frequency is doubled, the controller 560 may reduce the delay of the delay device 520 in half to maintain a delay of a quarter of a period by instructing the multiplexer 550 to switch to an output 545(1)-545(16) corresponding to a delay that is half the delay of the currently selected output 545(1)-545(16).

Thus, when the data frequency changes, the controller 560 adjusts the delay of the delay device 520 by instructing the multiplexer to switch the output 545(1)-545(16) of the delay elements 540(1)-540(16) selected by the multiplexer 550. This does not require making adjustments to the master PLL/DLL 510, and therefore does not require relocking the PLL/DLL 510. Switching the output 545(1)-545(16) selected by the multiplexer 550 can be performed much faster than relocking the PLL/DLL 510, and therefore avoids the long downtime associated with relocking the PLL/DLL 510. Thus, the downtime for data frequency switching is reduced. In addition, the delay device 520 uses one PLL/DLL, thereby avoiding the use of multiple PLLs/DLLs, which consume more power and chip area.

The delay device 520 may also be used to implement the second delay device 140 in the memory interface 105, in which the delay device 520 delays the data strobe signal 134 from the DRAM by a quarter of a period. When the data frequency changes, the controller 560 may adjust the delay of the delay device 520 accordingly in a manner similar to the manner discussed above for the first delay device 125. Although, the delay device 520 comprises 16 delay elements 540(1)-540(16) in the example shown in FIG. 5, it is to be appreciated that the delay device 520 may comprise fewer or more delay elements.

As discussed above, the voltage bias from the PLL/DLL 510 determines the step delay of each of the delay elements 540(1)-540(16) in the delay device 520. Thus, the step delay may be set to a desired step delay by setting the reference signal of the master PLL/DLL 510 to a frequency that achieves the desired step delay and/or setting the divisor N of the frequency divider 370 to a value that achieves the desired step delay. A smaller step delay allows the delay of the delay device 520 to be adjusted with finer granularity at the expense of requiring more delay elements 540(1)-540(16) to achieve a given amount of delay. A smaller step delay may be used when the memory interface needs to meet tighter timing constraints (e.g., for high-speed data transfer). Thus, the size of the step delay may depend on timing constraints placed on the memory interface and/or another parameter.

Embodiments of the present disclosure allow two or more delay devices to share the same master PLL/DLL 510. In this case, each of the delay devices may be implemented using the delay device 520 shown in FIG. 5, in which the delay elements in each of the delay devices are biased by the voltage bias from the master PLL/DLL 510. The delays of the delay devices can be independently adjusted. This is because the selection settings of their multiplexers can be independently controlled. Thus, the delay devices may have different delays even though they share the same master PLL/DLL 510.

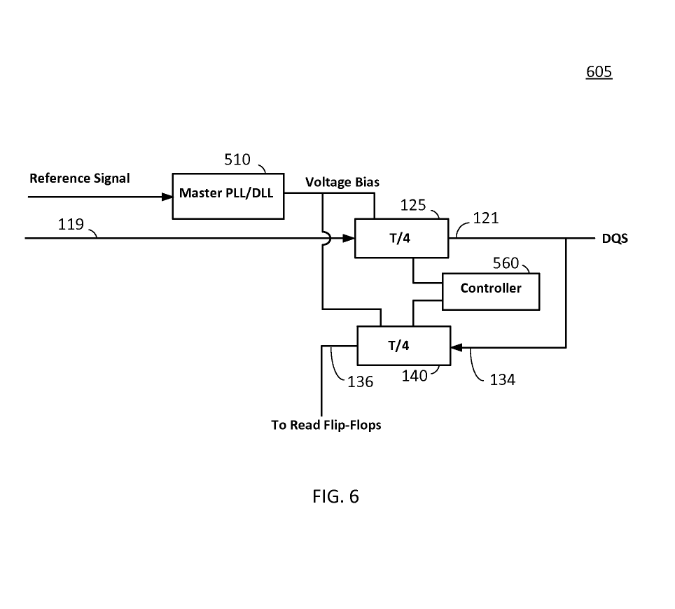

FIG. 6 shows a memory interface 605 according to an embodiment of the present disclosure, in which each of the first and second delay devices 125 and 140 is implemented using the delay device 520 shown in FIG. 5. For ease of illustration, the flip-flops and per-bit de-skew devices are not shown in FIG. 6. In this embodiment, the first and second delay devices 125 and 140 share the master PLL/DLL 510. The master PLL/DLL 510 provides the voltage bias to the delay elements in the first delay device 125 and the delay elements in the second delay devices 140.

The controller 560 adjusts the delay of the first delay device 125 by controlling the selection setting of the multiplexer of the first delay device 125. Similarly, the controller 560 adjusts the delay of the second delay device 140 by controlling the selection setting of the multiplexer of the second delay device 140. The controller 560 may independently control the selection settings of the multiplexers of the first and second delay devices 125 and 140, and therefore independently control the delays of the first and second delay devices 125 and 140.

When the data frequency changes, the controller 560 may adjust the delay of each of the first and second delay devices 125 and 140 to maintain a delay of a quarter of a period by switching the selection setting of the respective multiplexer accordingly. This does not require making adjustments to the master PLL/DLL 510, and therefore does not require relocking the PLL/DLL 510.

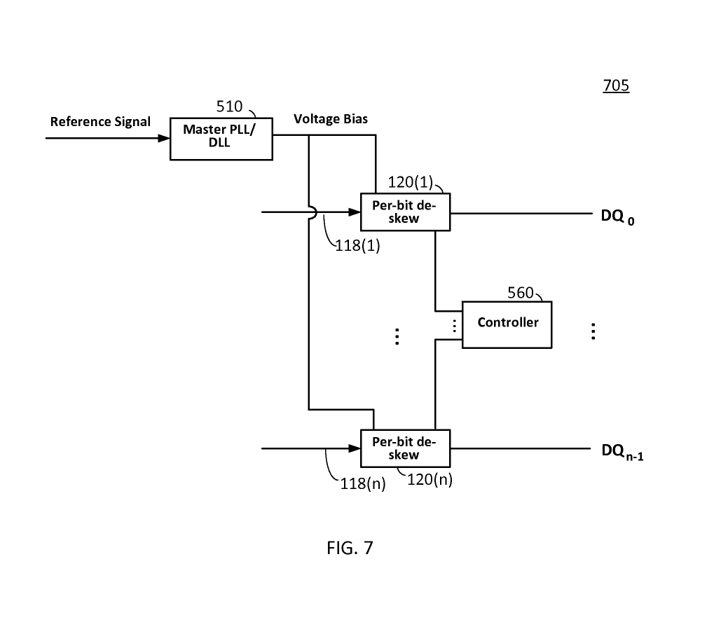

Each of the first plurality of per-bit de-skew devices 120(1)-120(n) may also be implemented using the delay device 520 shown in FIG. 5. In this regard, FIG. 7 shows a memory interface 705 according to an embodiment in which each of the per-bit de-skew devices 120(1)-120(n) is implemented using the delay device 520 in FIG. 5. For ease of illustration, the flip-flops, the second plurality of per-bit de-skew devices 145(1)-145(n), the first delay device 125, and the second delay device 140 are not shown in FIG. 7. In this embodiment, the per-bit de-skew devices 120(1)-120(n) share the master PLL/DLL 510. The per-bit de-skew devices 120(1)-120(n) may also share the master PLL/DLL 520 with the first and second delay devices 125 and 140. The master PLL/DLL 510 provides the voltage bias to the delay elements in each of the per-bit de-skew devices 120(1)-120(n).

The controller 560 adjusts the de-skew delay of each per-bit de-skew device 120(1)-120(n) by controlling the selection setting of the respective multiplexer. The controller 560 may independently control the selection settings of the multiplexers of the per-bit de-skew devices 120(1)-120(n), and therefore independently control the de-skew delays of the per-bit de-skew devices 120(1)-120(n).

In one embodiment, the controller 560 adjusts the de-skew delay of each per-bit de-skew device 120(1)-120(n) to compensate for skew between the respective data signal 118(1)-118(n) and the data strobe signal 121 in going from the memory interface 705 to the DRAM. Different data signals 118(1)-118(n) may have different skews due to differences in the data lines DQ₀-DQₙ₋₁. In this case, the controller 560 may independently adjust the de-skew delays of the per-bit de-skew devices 120(1)-120(n) to account for the different skews.

In one embodiment, the de-skew delay for each per-bit de-skew device 120(1)-120(n) may be determined by performing a test on the per-bit de-skew device 120(1)-120(n). The test may include setting the delay of the per-bit de-skew device 120(1)-120(n) to a plurality of different delays, performing a write operation for each of the delays, and determining whether the write operation was successful for each of the delays. Each write operation may include writing a sequence of bits to the DRAM. For each write operation, a determination may be made whether the write operation was successful by reading back the sequence of bits from the DRAM and comparing the read sequence of bits with the sequence of bits sent to the DRAM. The sequence of bits may be read back at a slow data frequency to ensure that the read operation is accurate, and therefore that any differences between the read sequence of bits and the sequence of bits sent to the DRAM are due to the write operation. The controller 560 may then be programmed to set the de-skew delay for the per-bit de-skew device 120(1)-120(n) to a delay for which the write operation was determined to be successful during testing. If a plurality of the write operations were successful over a range of the delays during testing, then the controller 560 may be programmed to set the de-skew delay for the per-bit de-skew device 120(1)-120(n) to a delay approximately in the center of the range of delays.

The above test may be performed for each per-bit de-skew device 120(1)-120(n) to determine the de-skew delay for each per-bit de-skew device 120(1)-120(n). Once, the de-skew delay for each per-bit de-skew device 120(1)-120(n) is determined, the controller 560 may be programmed to adjust the delay of each per-bit de-skew device 120(1)-120(n) to the respective de-skew delay.

In one embodiment, each per-bit de-skew device 120(1)-120(n) may have a plurality of different de-skew delays corresponding to different data frequencies. For each per-bit de-skew device 120(1)-120(n), the de-skew delay for each data frequency may be determined by performing the above test at each data frequency. At each data frequency, the write operations for the test may be performed at the data frequency while the read back operations used to check the write operations may be performed at a lower data frequency. Once the de-skew delays are determined for one of the per-bit de-skew devices 120(1)-120(n), the controller 560 may be programmed with the de-skew delays and associate each of the de-skew delays with the corresponding data frequency.

Thus, the controller 560 may be programed with a plurality of de-skew delays for each per-bit de-skew 120(1)-120(n), in which each de-skew delay corresponds to a different data frequency. When the data frequency of the memory interface 705 changes to a new data frequency, the controller 560 may adjust the delay of each per-bit de-skew device 120(1)-120(n) to the de-skew delay programmed for the per-bit de-skew device at the new data frequency.

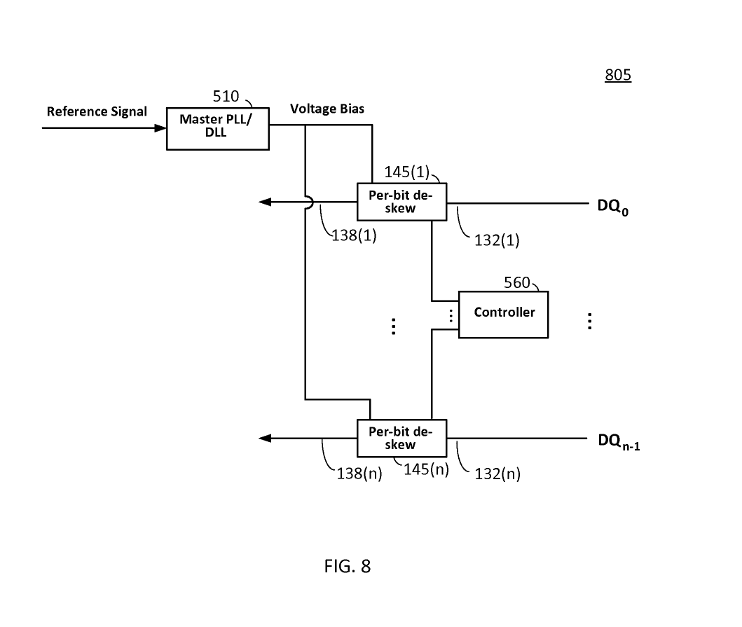

Each of the second plurality of per-bit de-skew devices 145(1)-145(n) may also be implemented using the delay device 520 shown in FIG. 5. In this regard, FIG. 8 shows a memory interface 805 according to an embodiment in which each of the per-bit de-skew devices 145(1)-145(n) is implemented using the delay device 520 in FIG. 5. For ease of illustration, the flip-flops, the first plurality of per-bit de-skew devices 120(1)-120(n), the first delay device 125, and the second delay device 140 are not shown in FIG. 7. In this embodiment, the per-bit de-skew devices 145(1)-145(n) share the master PLL/DLL 510. The per-bit de-skew devices 145(1)-145(n) may also share the master PLL/DLL 520 with the first and second delay devices 125 and 140 and/or the first plurality of per-bit de-skew devices 120(1)-120(n). The master PLL/DLL 510 provides the voltage bias to the delay elements in each of the per-bit de-skew devices 145(1)-145(n).

The controller 560 adjusts the de-skew delay of each per-bit de-skew device 145(1)-145(n) by controlling the selection setting of the respective multiplexer. The controller 560 may independently control the selection settings of the multiplexers of the per-bit de-skew devices 145(1)-145(n), and therefore independently control the de-skew delays of the per-bit de-skew devices 145(1)-145(n).

In one embodiment, the controller 560 adjusts the de-skew delay of each per-bit de-skew device 145(1)-145(n) to compensate for skew between the respective data signal 132(1)-132(n) and the data strobe signal 134 in going from the DRAM to the memory interface 805. Different data signals 132(1)-132(n) may have different skews due to differences in the data lines DQ₀-DQₙ₋₁. In this case, the controller 560 may independently adjust the de-skew delays of the per-bit de-skew devices 145(1)-145(n) to account for the different skews.

In one embodiment, the de-skew delay for each per-bit de-skew device 145(1)-145(n) may be determined by performing a test on the per-bit de-skew device 145(1)-145(n). The test may include setting the delay of the per-bit de-skew device 145(1)-145(n) to a plurality of different delays, performing a read operation for each of the delays, and determining whether the read operation was successful for each of the delays. Each read operation may include reading a sequence of bits from the DRAM, in which the sequence of bits was previously written to the DRAM by the memory interface 805 at a slow data frequency. For each read operation, a determination may be made whether the read operation was successful by comparing the sequence of bits read from the DRAM with the sequence of bits sent to the DRAM. The controller 560 may then be programmed to set the de-skew delay for the per-bit de-skew device 145(1)-145(n) to a delay for which the read operation was determined to be successful during testing. If a plurality of the read operations were successful over a range of the delays during testing, then the controller 560 may be programmed to set the de-skew delay for the per-bit de-skew device 145(1)-145(n) to a delay approximately in the center of the range of delays.

The above test may be performed for each per-bit de-skew device 145(1)-145(n) to determine the de-skew delay for each per-bit de-skew device 145(1)-145(n). Once, the de-skew delay for each per-bit de-skew device 145(1)-145(n) is determined, the controller 560 may be programmed to adjust the delay of each per-bit de-skew device 145(1)-145(n) to the respective de-skew delay.

In one embodiment, each per-bit de-skew device 145(1)-145(n) may have a plurality of different de-skew delays corresponding to different data frequencies. For each per-bit de-skew device 145(1)-145(n), the de-skew delay for each data frequency may be determined by performing the above test at each data frequency. At each data frequency, the read operations for the test may be performed at the data frequency while the write operation used to the write the sequence of bits to the DRAM may be performed at a lower data frequency. Once the de-skew delays are determined for one of the per-bit de-skew devices 145(1)-145(n), the controller 560 may be programmed with the de-skew delays and associate each of the de-skew delays with the corresponding data frequency.

Thus, the controller 560 may be programed with a plurality of de-skew delays for each per-bit de-skew 145(1)-145(n), in which each de-skew delay corresponds to a different data frequency. When the data frequency of the memory interface 805 changes to a new data frequency, the controller 560 may adjust the delay of each per-bit de-skew device 145(1)-145(n) to the de-skew delay programmed for the per-bit de-skew device at the new data frequency.

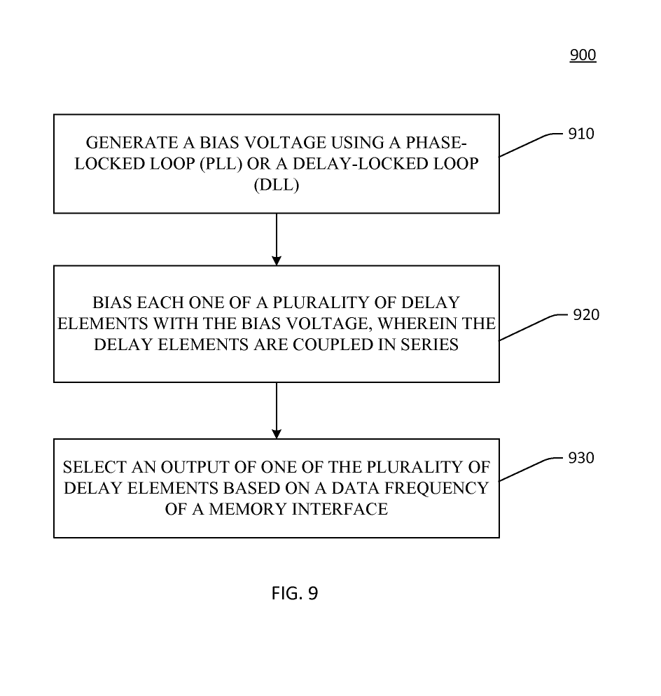

FIG. 9 is a flow diagram illustrating a method 900 for signal delay according to an embodiment of the present disclosure.

In step 910, a bias voltage is generated using a phase-locked loop (PLL) or a delay-locked loop (DLL). For example, the bias voltage may be generated by a master PLL/DLL (e.g., the master PLL/DLL 510).

In step 920, each one of a plurality of delay elements is biased with the bias voltage, wherein the delay elements are coupled in series. For example, each of the delay elements (e.g., delay elements 540(1)-540(16)) may be biased with the bias voltage generated by the master PLL/DLL (e.g., master PLL/DLL 510).

In step 930, an output of one of the plurality of delay elements is selected based on a data frequency of a memory interface. For example, the outputs of the delay elements (e.g., delay elements 540(1)-540(16)) may be coupled to a multiplexer (e.g., multiplexer 550), and the multiplexer may select the output of one of the delay elements.

The controller 560 may be implemented with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may perform the functions of the controller 560 described herein by executing software comprising code for performing the functions. The software may be stored on a computer-readable storage medium, such as a RAM, a ROM, an EEPROM, an optical disk, and/or a magnetic disk.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. For example, although embodiments of the present disclosure are discussed above using an example of a DRAM, it is to be appreciated that embodiments of the present disclosure are not limited to this example, and may be used with other types of memory devices. Thus, the disclosure is not intended to be limited to the examples described herein but is to be accorded the widest scope consistent with the principles and novel features disclosed herein.

What is claimed is:

1. An adjustable delay circuit, comprising:
a phase-locked loop (PLL) configured to generate a bias voltage;
a plurality of delay elements coupled in series, wherein each of the delay elements is biased by the bias voltage; and
a multiplexer coupled to outputs of two or more of the delay elements, wherein each of the outputs corresponds to a different delay of an input signal, and wherein the multiplexer is configured to select one of the outputs based on a data frequency of a memory interface.

2. The delay circuit of claim 1, wherein the multiplexer is configured to select a different one of the outputs if the data frequency changes.

3. The delay circuit of claim 2, wherein the bias voltage remains substantially constant when the data frequency changes.

4. The delay circuit of claim 3, wherein a frequency of a reference signal input to the PLL remains substantially constant when the data frequency changes.

5. The delay circuit of claim 3, wherein the PLL includes a frequency divider and a divisor of the frequency divider remains substantially constant when the data frequency changes.

6. The delay circuit of claim 1, wherein the input signal comprises a data strobe signal, and the multiplexer is configured to select one of the outputs corresponding to a delay of a quarter of a period of the data strobe signal.

7. The delay circuit of claim 1, wherein the input signal comprises a data signal, and the multiplexer is configured to select one of the outputs corresponding to a de-skew delay that compensates for skew between the data signal and a data strobe signal.

8. An adjustable delay circuit, comprising:
a delay-locked loop (DLL) configured to generate a bias voltage;
a plurality of delay elements coupled in series, wherein each of the delay elements is biased by the bias voltage; and
a multiplexer coupled to outputs of two or more of the delay elements, wherein each of the outputs corresponds to a different delay of an input signal, and wherein the multiplexer is configured to select one of the outputs based on a data frequency of a memory interface.

9. The delay circuit of claim 8, wherein the multiplexer is configured to select a different one of the outputs if the data frequency changes.

10. The delay circuit of claim 9, wherein the bias voltage remains substantially constant when the data frequency changes.

11. The delay circuit of claim 10, wherein a frequency of a reference signal input to the DLL remains substantially constant when the data frequency changes.

12. The delay circuit of claim 8, wherein the input signal comprises a data strobe signal, and the multiplexer is configured to select one of the outputs corresponding to a delay of a quarter of a period of the data strobe signal.

13. The delay circuit of claim 8, wherein the input signal comprises a data signal, and the multiplexer is configured to select one of the outputs corresponding to a de-skew delay that compensates for skew between the data signal and a data strobe signal.

14. A method for signal delay, comprising:
generating a bias voltage using a phase-locked loop (PLL) or a delay-locked loop (DLL);
biasing each one of a plurality of delay elements with the bias voltage, wherein the plurality of delay elements are coupled in series; and
selecting an output of one of the plurality of delay elements based on a data frequency of a memory interface.

15. The method of claim 14, further comprising selecting an output of a different one of the plurality of delay elements if the data frequency changes.

16. The method of claim 15, wherein the bias voltage remains substantially constant when the data frequency changes.

17. The method of claim 16, wherein a frequency of a reference signal input to the PLL or the DLL remains substantially constant when the data frequency changes.

18. The method of claim 14, wherein selecting the output of one of the plurality of delay elements comprises selecting the output of one of the plurality of delay elements corresponding to a delay of a quarter of a period of a data strobe signal.

19. The method of claim 14, wherein selecting the output of one of the plurality of delay elements comprises selecting the output of one of the plurality of delay elements corresponding to a de-skew delay that compensates for skew between a data signal and a data strobe signal.

20. An apparatus for signal delay, comprising:
means for generating a bias voltage;
means for biasing each one of a plurality of delay elements with the bias voltage, wherein the plurality of delay elements are coupled in series; and
means for selecting an output of one of the plurality of delay elements based on a data frequency of a memory interface.

21. The apparatus of claim 20, further comprising means for selecting an output of a different one of the plurality of delay elements if the data frequency changes.

22. The apparatus of claim 21, wherein the bias voltage remains substantially constant when the data frequency changes.

23. The apparatus of claim 22, wherein a frequency of a reference signal input to the means for generating the bias voltage remains substantially constant when the data frequency changes.

24. The apparatus of claim 20, wherein the means for selecting the output of one of the plurality of delay elements is configured to select the output of one of the plurality of delay elements corresponding to a delay of a quarter of a period of a data strobe signal.

25. The apparatus of claim 20, wherein the means for selecting the output of one of the plurality of delay elements is configured to select the output of one of the plurality of delay elements corresponding to a de-skew delay that compensates for skew between a data signal and a data strobe signal.
